(19) United States
(12) Patent Application Publication
(10) Pub. No.: US 2019/0371952 A1
(43) Pub. Date: Dec. 5, 2019

(54) BIFACIAL SOLAR MODULE

(71) Applicant: FLEX LTD., Singapore (SG)

(72) Inventor: Lisong Zhou, Fremont, CA (US)

(21) Appl. No.: 16/427,048

(22) Filed: May 30, 2019

Related U.S. Application Data
(60) Provisional application No. 62/677,916, filed on May 30, 2018.

(51) Int. Cl. H01L 31/068; H01L 31/048; H01L 31/05; H01L 31/054; H02S 30/10

(52) U.S. Cl. CPC H01L 31/0684; H01L 31/048; H02S 30/10; H01L 31/0547; H01L 31/0504

(57) ABSTRACT

Bifacial solar modules with enhanced power output are described herein including a first and second transparent support layer, a first and second encapsulating layer, a plurality of electrically interconnected bifacial solar cells with gaps between the interconnected bifacial solar cells, and one or more highly reflective films or coatings attached to the solar module at the gaps between the bifacial solar cells or an edge gap at a peripheral edge of the solar module beyond the bifacial solar cells, wherein the films or coatings redirect light impacting them such that the light is directed towards at least one of the bifacial solar cells.

### TECHNICAL FIELD

This present disclosure relates to solar energy production. More specifically a solar module design incorporating light management that increases power output for the same or less amount of silicon solar cells.

### BACKGROUND

Solar power is accelerating as a mainstream power generation source in global markets. In order to further broaden its economic value, greater productivity of solar power system is desired by customers. Crystalline solar photovoltaic systems predominantly capture light on the front side of solar panels, on the front “face”, which can be considered “monofacial” solar panels. One method to increase power production is to harvest reflected light from the ground on the back side of the solar panels, on to special solar cells, that are designed to harvest “bifacial” energy. Bifacial solar panels have been used in the solar industry for over 10 years.

There are several key limitations on the design of bifacial solar panels that limit their utility. Initially, there is light loss through the solar panel, around the crystalline solar cells, impacted front side power. Typical crystalline modules have significant areas between the cells that are not covered by active solar cell material. Light entering these zones on a monofacial module is largely reflected, and scattered, by standard white back sheets, and partially recovered through total internal refection (TIR) onto the front sides of solar cells. On bifacial modules however, this light energy is lost because the backside of the solar panel is transparent, per design, to allow the back of the cells to receive light. While this is necessary for rear side bifaciality, front side power suffers, approximately 3-5%. This is significant loss of power.

A second limitation is caused by lower backside irradiance at the edge of the solar panel due to the partial shading of edge cells from frame profile or mounting rail elements. Frames are desirable to reduce breakage of solar panels, enable a more durable long term solar panel life, and reduce mounting system costs. However, frames have profiles that extend beyond the lower plane of the module back sheet. As a result, cell columns near the edge of the module receive less light than cells further away from the edge.

The present disclosure addresses all of these shortcomings of the known systems.

### SUMMARY

One aspect of the present disclosure describes systems and methods for increasing power output from a solar module containing bifacial solar cells by applying light management films, foils, or coatings which causes direct and total internal reflection in the module to redirect light from blank regions between the cells back to both active cell surfaces, cell front and back junctions. In particular the present disclosure is directed to shingled solar modules employing these power product improvements.

Another aspect of the present disclosure describes a bifacial solar module with enhanced power output is provided including a first transparent support layer, a first encapsulating layer, a plurality of electrically interconnected bifacial solar cells with gaps between the interconnected bifacial solar cells, a second encapsulating layer, a second transparent support layer, and one or more highly reflective films or coatings attached to the solar module at the gaps between the bifacial solar cells or an edge gap at a peripheral edge of the solar module beyond the bifacial solar cells, wherein the films or coatings redirect light impacting them such that the light is directed towards at least one of the bifacial solar cells.

In some embodiments, the first encapsulating layer and the second encapsulating layer are arranged between the first and second transparent support layers and the plurality of electrically interconnected bifacial solar cells are arranged between the first and second encapsulating layers.

In some embodiments, the one or more highly reflective films or coatings are positioned on an outer surface of at least one of the first or second transparent support layers.

In some embodiments, the one or more highly reflective films or coatings are positioned between the first transparent support layer and the first encapsulating layer, the second transparent support layer and the second encapsulating layer, or both.

In some embodiments, the one or more highly reflective films or coatings are encapsulated within the same layer of the solar cells and positioned within the gaps.

In some embodiments, the one or more highly reflective films or coatings are vertically aligned with at least one of the gaps or edge gaps of the solar module.

Another aspect of the present disclosure describes a framed bifacial solar module with enhanced power output including a frame configured to receive and secure a bifacial solar module, the bifacial module including a first and second transparent support layer, a first and second encapsulating layer arranged between the first and second transparent support layers, a plurality of electrically interconnected bifacial solar cells with gaps between the interconnected bifacial solar cells and arranged between the first and second encapsulating layers, and one or more highly reflective films or coatings attached to the solar module at the gaps between the bifacial solar cells or an edge gap at a peripheral edge of the solar module beyond the bifacial solar cells, wherein the films or coatings redirect light impacting them such that the light is directed towards at least one of the bifacial solar cells.

In some embodiments, the frame includes a side wall having a length defined between a first and second end thereof, the first end having a top support wall extending therefrom, the second end having a bottom support wall extending therefrom, and a portion along the length of the frame between the first and second ends including an intermediate support wall extending therefrom, wherein the bifacial solar module is received and secured within the frame between the top and intermediate support walls of the frame.

In some embodiments, the one or more highly reflective films or coatings are positioned on a surface of the second bottom support wall facing the solar module.

In some embodiments, the one or more highly reflective films or coatings are further positioned on an inner surface of the sidewall between the second bottom support wall and the intermediate support wall.

In some embodiments, the one or more highly reflective films or coatings are positioned at an angle relative to the solar module and extending from the sidewall near the intermediate support wall towards a free end of the second bottom support wall.

Another aspect of the present disclosure describes a solar power kit including one of the framed or frameless solar modules described herein.

### BRIEF DESCRIPTION OF DRAWINGS

FIG. 1 depicts a cross-sectional sideview of a frameless bifacial solar module;

FIG. 2 depicts a cross-sectional sideview of framed bifacial solar module;

FIG. 3 depicts the shading effect of a framed bifacial solar module;

FIGS. 4A-4G depict a cross-sectional sideview of a variety of arrangements of highly reflective films or highly reflective coatings in a frameless bifacial solar module;

FIGS. 5A-5I depict a cross-sectional sideview of a variety of arrangements of highly reflective films or highly reflective coatings in a framed bifacial solar module; and

FIGS. 6A-6F depict a cross-sectional sideview of a variety of arrangements of highly reflective films or highly reflective coatings in a framed bifacial solar module.

### DETAILED DESCRIPTION

The present disclosure is directed to systems and methods for increasing the energy yield of bifacial solar modules. The increase in energy yield is a result of redirecting light that would normally not be captured by the module, due to shading or gaps in solar cell coverage, back onto an active face of a solar cell.

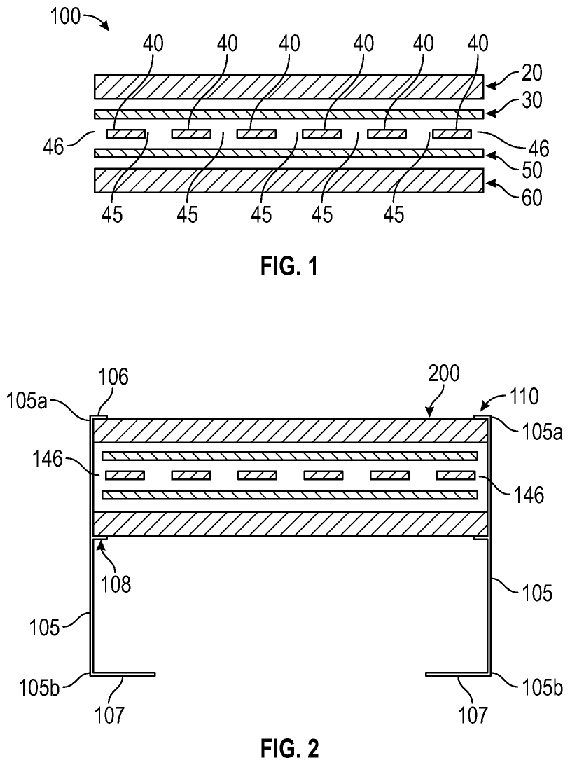

FIG. 1 shows an arrangement of a frameless bifacial solar module 100 in cross-section with each of the layers or parts separated vertically from each other to provide a better view of each of the layers or parts described herein. Module 100 includes first and second transparent support layers 20, 60, first and second encapsulation layers 30, 50 positioned therebetween, and one or more bifacial solar cells 40 spaced apart horizontally from each other by gap 45 and positioned between the first and second encapsulation layers 30, 50. In use, the layers or parts described herein are generally stacked in physical contact with each other without the separation.

In accordance with the present disclosure the solar cells 40 are shingled solar cells formed into strings that are separated from one another to form the gaps 45 through which light can pass. Details of forming a solar module using shingling techniques can be found in U.S. Pat. No. 9,935,221 to Zhou et al and entitled “Shingled Array Solar Cells and Method of Manufacturing Solar Modules Including the Same,” issued Apr. 3, 2018, and incorporated herein by reference.

The first transparent support layer 20 and the second transparent support layer 60 each form an outer protective layer for the cells 40 which allows light to pass therethrough to the inside of the module. The first and second transparent support layers 20, 60 also shield the contents inside the module from the physical forces of nature, such as rain, wind, snow, etc. The transparent support layers 20, 60 extend beyond the cells 40 creating an edge gap 46 between the outer edge of the module and the outermost cells 40. The transparent support layers 20, 60 are made of any suitable material including but not limited to glass or transparent polymers, such as polycarbonate, polymethylmethacrylate, polyethylene terephthalate, polypropylene, polyvinyl fluoride, polyvinylidene fluoride, fluoroethylene and vinyl ether copolymer, or other fluoropolymer.

The first encapsulation layer 30 is positioned between and separates the first transparent support layer 20 from the layer of solar cells 40. The second encapsulation layer 50 is positioned between and separates the second transparent support layer 60 from the layer of solar cells 40. The first and second encapsulation layers 30, 50 connect to the first and second transparent support layers 20, 60, respectively, on an outer surface thereof. The first and second encapsulation layers 30, 50 also connect to the layer of solar cells 40 on an inner surface thereof. The encapsulation layers 30, 50 allow light to pass therethrough to the solar cells positioned in the center thereof. The first and second encapsulant layers described herein are made of any suitable material including but not limited to, polymers or copolymers of ethylene acid, ionomers of ethylene acid copolymer, poly (ethylene vinyl acetate), poly (vinyl acetal), polyurethane, polyvinyl chloride, polyethylene, polyolefin block copolymers elastomers, poly (α-olefin-co- α,β-ethylenically unsaturated carboxylic acid ester) copolymer, silicone elastomer, epoxy resin, polyimide, fluoropolymer resins, and combinations thereof.

In the layer of solar cells 40, the edges of any two neighboring solar cells 40 are spaced apart providing a gap 45 therebetween. The gap 45 has a substantially uniform width (taking into account manufacturing, material, and environmental tolerances) between the two adjacent cells 40 of about 0.5 mm to about 50 mm. In some embodiments, the gap 45 has a substantially uniform width of about 1 mm to about 25 mm. In some embodiments, the gap 45 has a substantially uniform width of about 2 mm to about 5 mm.

The outer edges of the solar module and the outside edge of the outermost cells closest to the outer edge of the solar module create edge gaps 46 having a substantially uniform width (taking into account manufacturing, material, and environmental tolerances) between about 0.5 mm to about 50 mm. In some embodiments, the edge gap 46 has a substantially uniform width of about 1 mm to about 25 mm. In some embodiments, the gap 45 has a substantially uniform width of about 2 mm to about 5 mm. In some embodiments, the edge gap 46 has a width smaller than a width of the gap 45. In some embodiments, the edge gap 46 has a width larger than a width of the gap 45.

The cells 40, although shown separated by the gap 45, may still be electrically connected in parallel or series using any suitable method. In one embodiment, each cell 40 is connected in series to the next cell 40 with a single positive and negative terminal for the solar panel module 100. Alternatively, in some embodiments, bus bars may be employed to allow for connection of some or all of the cells 40 in parallel. The electrical connections may depend on the vehicle, its battery charging voltages, and the minimization of shadowing effects.

FIG. 2 shows an arrangement of a framed bifacial solar module 200, depicting a frame 110 in addition to the components depicted in FIG. 1. Frame 110 includes a cross-section having a side wall 105 having a length defined between a first and second end 105a, 105b thereof, the first end 105a having a first support wall 106 extending therefrom, the second end 105b having a second support wall 107 extending therefrom, and a portion along the length of the frame 110 between the first and second ends 105a, 105b including an intermediate support wall 108 extending therefrom, wherein the bifacial solar module 200 is received and secured within the frame 110 between the first and intermediate support walls 106, 108 of the frame 110. As shown, each of the support walls 106, 107, 108 extend inwardly towards the solar module 200 from the sidewall 105 to be configured to receive and store a bifacial solar module 200 between at least two of the support walls 106, 107, 108. Each of the support walls 106, 107, 108 being generally parallel to each other and generally perpendicular to the side wall 105.

In some embodiments, at least the first and intermediate support walls 106, 108 are spaced apart from each other a distance generally equal to a thickness of the solar module 200. In some embodiments, each of the support walls 106, 107, 108 are each spaced apart from each other a distance generally equal to a thickness of the solar module 200.

In some embodiments, the first and intermediate support walls 106, 108 have a length smaller than a length of the second support wall 107. In some embodiments, the first and intermediate support walls 106, 108 have a length generally equal to the edge gap 146. In some embodiments, the lower support wall 107 has a length greater than the edge gap 146.

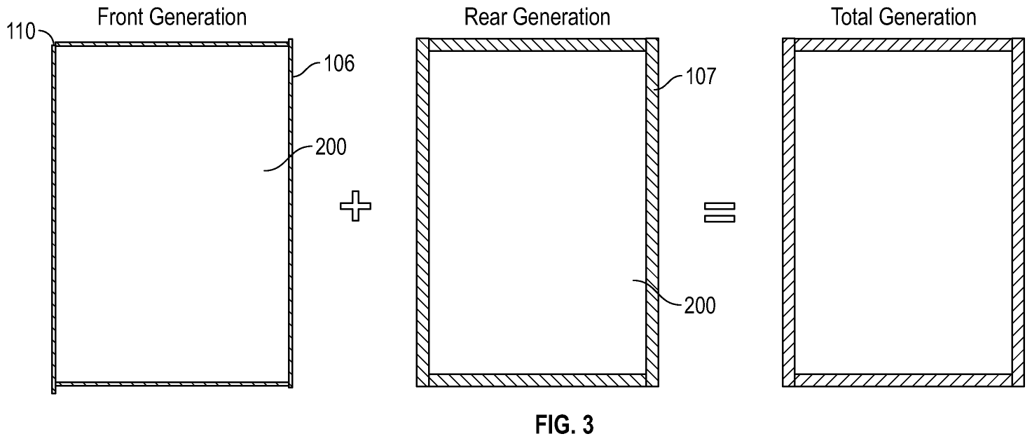

FIG. 3 depicts the shading effects of a frame 110 surrounding a bifacial solar module 200. Solar cells are generally agnostic as to the side of the cell which receives the power, when one side or the other in a string of series connected solar cells is shaded, the output current of that solar cell will be reduced, and the power production of the string will be limited due to the current limit of that shade solar cells. The result is that the side strings of cells produce less power that the middle strings of cells, and thus affect the total output of the entire module. As a result, though having solar cells exposed to both front and rear illumination, the actual power output of the framed bifacial solar panel is less than the combined output of a frameless bifacial solar panel under the same illumination.

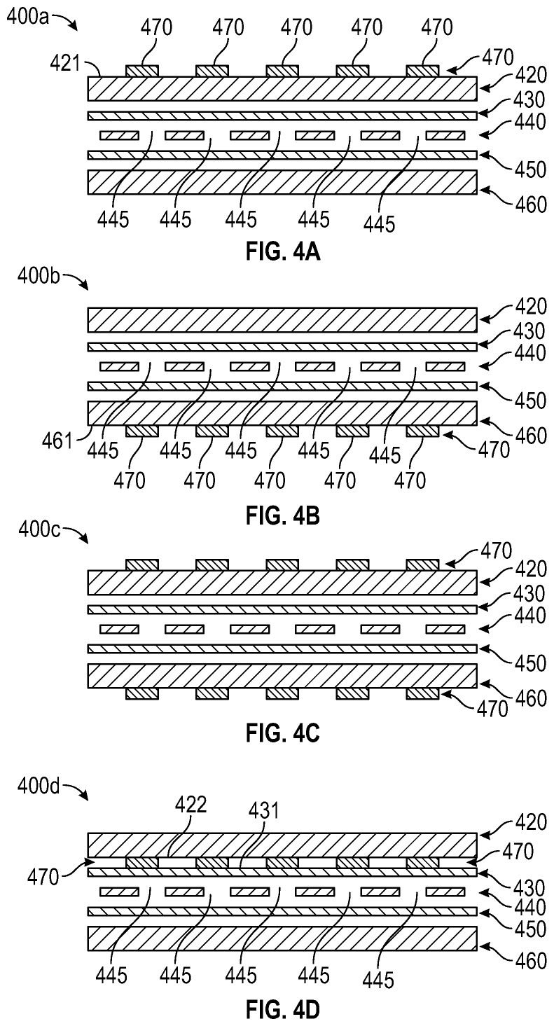

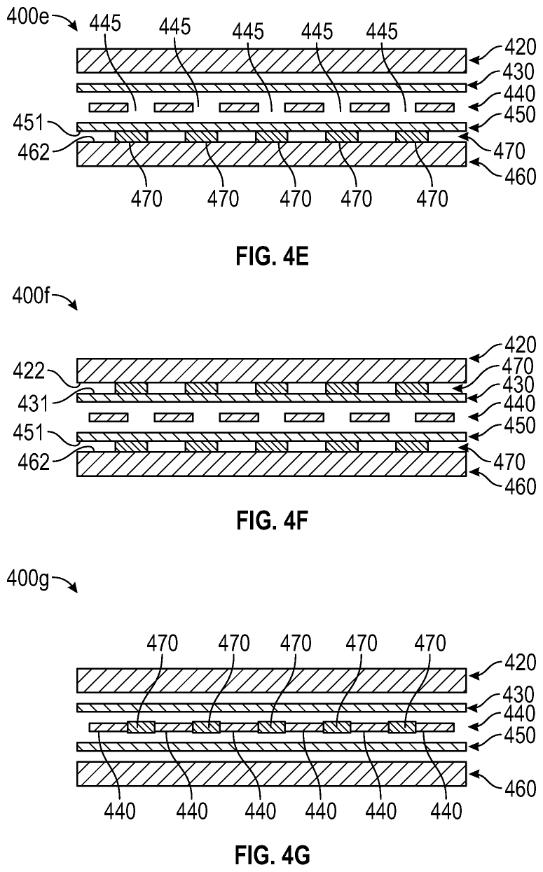

FIGS. 4A-6E depict a variety of placements of sheets or strips of highly reflective materials (HRM), such as highly reflective films or foils (HRF) or highly reflective coatings (HRC), that may be employed to address this shading effect. These highly reflective materials generally have a high reflectivity in the targeted solar spectrum, and function like a mirror. In some embodiments, the highly reflective material is preformed into strips or sheets of a film prior to incorporation into the solar module. The films or foils can be secured to the solar module or frame using an adhesive or can be molded, laminated, pressed, or melt-adhered, to the solar module. In some embodiments, the highly reflective material is incorporated into the solar module as a coating which ultimately forms the sheet or strip of highly reflective material after incorporation into the solar module. For example, the highly reflective coating may be a liquid applied to a portion of the solar module which ultimately dries or hardens into a solid strip or sheet of highly reflective material. The liquid may be applied using any suitable method including extrusion, lamination, spraying, molding, pouring, dipping, wiping, etc.

The highly reflective films or coatings can be formed using any suitable reflective material including, but not limited to, reflective polymers such as polyethylene terephthalate (PET), triacetate cellulose (TAC), and ethylene tetrafluoroethylene (ETFE), reflective metals such as aluminum, silver, gold, copper, palladium, platinum, or alloys, ceramic materials, paint, or materials formed in the prism shaped, or combinations thereof.

In general, regardless of HRF or HRC, if the highly reflective material is placed on the underside of the solar module, as depicted at least in part of FIGS. 4B, 4C, 4E, 4F, 5B, 5C, 5E, 5F, 5H, 5I, and 6D-6F, the purpose is to reflect light that passes through the front side of the solar module, and would otherwise have passed completely through the module, at some angle back towards the backside of the solar cells. As can be seen the HRF or HRC can be placed on the exterior of the solar module. Alternatively, the films or coatings can become part of the layup of the solar module and be integrated into the solar module at a variety of locations.

In the embodiments where the HRF or HRC is on substantially the same plane as the solar cells, as depicted at least in part of FIGS. 4G, 5G, and 6C, the film or coating reflects light back towards the front side glass, preferably at an angle, such that the light reflects internally off of the glass and is captured by the solar cells to produce electrical energy.

In embodiments where the HRF or HRC is above the front side of the solar cells (the side directly facing the sun), as depicted at least in part of FIGS. 4A, 4C, 4D, 4F, 5A, 5C, 5D, 5F, 6A, and 6B, the purpose of the HRC or HRF is less to reflect the sunlight, and more to deflect the sunlight. In these solutions, the film or coating may be opaque or even clear and include one or more features the deflect the sunlight from its straight path through the solar module and allow the sunlight to impact the electrical energy generating portions of the solar cells. This may be also be accomplished by etching one side or the other of the glass which forms the solar module at the locations where the film or coating might be applied and achieve the same or a similar effect. Alternatively, the HRC or HRF may include one or more prisms or prismatic materials that can deflect or bend the light entering them to ensure that rather than passing directly through the solar module, the sunlight impacts the solar cells.

FIGS. 4A-4G depict a frameless bifacial solar module 400a-g in cross-section with each of the layers or parts separated vertically from each other to provide a better view of each of the layers or parts described herein. In use, the layers or parts described herein are generally stacked in physical contact with each other without the separation.

The modules 400a-g each include a plurality of strips of the HRF or HRC 470, first and second transparent support layers 420, 460, first and second encapsulation layers 430, 450, and one or more bifacial solar cells 440 spaced apart horizontally from each other by gap 445. The solar cells 440 are positioned between the first and second encapsulation layers 430, 450. The encapsulation layers 430, 450 positioned between the first and second transparent support layers 420, 460. The plurality of strips of the HRF or HRC 470 are positioned intermittently across a width of the solar module 400a-g and along various layers of the modules 400a-g. In some embodiments, each strip of the HRF or HRC 470 is vertically aligned with the gaps 445 between the solar cells 440, such that each strip of HRF or HRC 470 extends a length generally equal to the width of the gaps 445 between the solar cells 440.

In some embodiments, as shown in FIGS. 4A-4C, the strips of the HRF or HRC 470 are positioned on at least one of the outside surfaces 421, 461 of the first or second transparent support layers 420, 460. In such embodiments, the strips of HRF or HRC 470 may include an adhesive (not shown) to secure each strip 470 to the outer surface 421, 461. When positioned on an outer surface 421, 461, each strip 470 may be added or applied separately either before formation of the solar module or after the formation of the solar module.

In some embodiments, as shown in FIGS. 4D-4G, the strips of the HRF or HRC 470 are positioned on at least one inside surface of the solar module 400d-g. For example, in some embodiments, the strips of the HRF or HRC may be positioned between the first transparent support layer 420 and the first encapsulation layer 430, the second transparent support layer 460 and the second encapsulation layer 450, or both (see, e.g., FIGS. 4D-4F). In such embodiments, the strips of HRF or HRC 470 may be in secured to at least one of an inner surface of the first or second transparent support layers 422, 462 or an outer surface of the first or second encapsulant layers 431, 451. One of the benefits of being positioned within the layers of the solar module include the lack of direct exposure to the outside environment including wind, rain, hail, snow, and the like which when positioned on the outer surface of the module can cause the HRF or HRC to wear away, partially curl, or become detached at least in part from the solar module which can greatly reduce the reflective ability of the highly reflective materials. When positioned between the first and second transparent support layers of the solar module, the highly reflective materials are shielded from at least a majority of the outside environment and are maintained in a flat, non-rolled configuration, and also prevented from becoming detached from the solar module.

As shown in FIG. 4G, in some embodiments, the strips of HRF or HRC 470 are encapsulated within the center of the solar module between the first and second encapsulant layers 430, 450 and positioned within the gaps 445 between the solar cells 440. In such embodiments, each of the strips 470 fill the gap 445 in the same plane as the solar cells 440. One of the benefits of being positioned along the same layer or plane as the solar cells 440 is that each strip 470 fails to cast a shadow on either active face of the bifacial cells 440. Thus, the encapsulated strips of HRC or HRF 470 positioned within the encapsulant layers 430, 450 and between the solar cells 440 increase productivity of the cells by decreasing shading on either active face of the bifacial cells 440.

In some embodiments, the plurality of strips of HRF or HRC may be positioned all within the same layer of the solar module (see, e.g., FIGS. 4A, 4B, 4D, 4E, 4G). In some embodiments, the plurality of strips of HRF or HRC may be positioned in two or more different layers of the solar module (see, e.g., FIGS. 4C and 4F). In some embodiments, the plurality of strips of HRF or HRC may be positioned only on an inside surface of the solar module. (see, e.g., FIGS. 4D-4G). In some embodiments, the plurality of strips of HRF or HRC may be encapsulated within the center of the solar module with the solar cells (see, e.g., FIG. 4G).

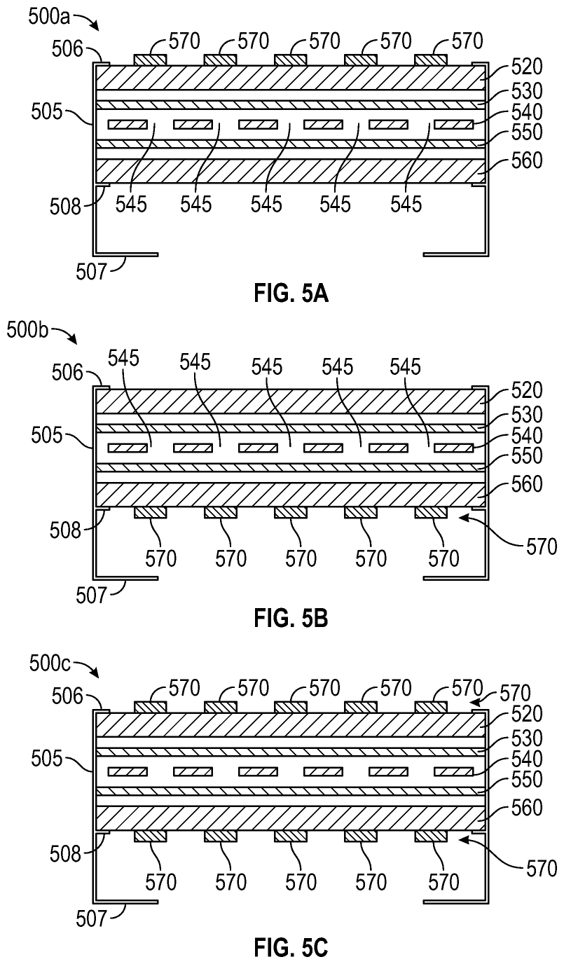

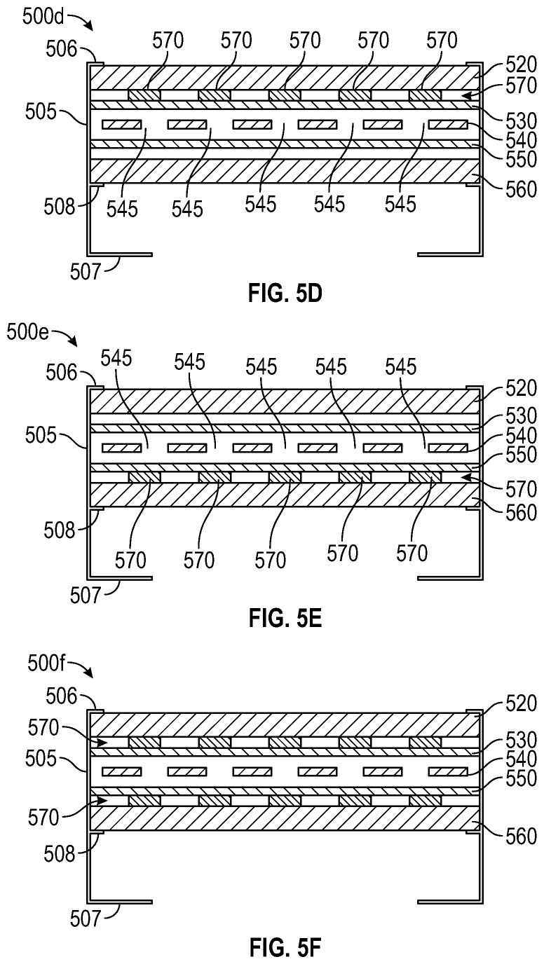

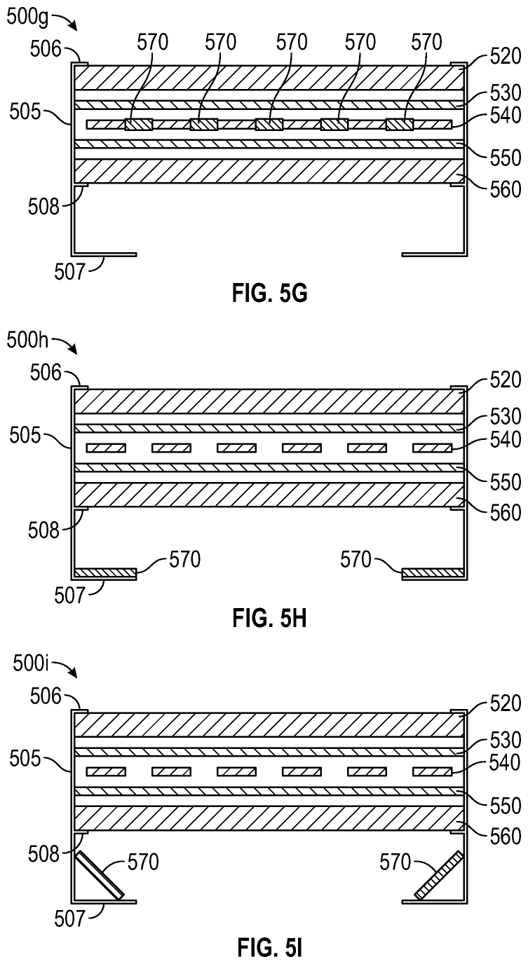

FIGS. 5A-5I depict, in some embodiments, a cross-section of a framed bifacial solar module 500a-i, depicting a frame 510 including a side wall 505 having a length defined between a first and second end 505a, 505b thereof, the first end 505a having a first support wall 506 extending therefrom, the second end 505b having a second support wall 507 extending therefrom, and a portion along the length of the frame 510 between the first and second ends 505a, 105b including an intermediate support wall 508 extending therefrom, wherein the bifacial solar module 500a-i is received and secured within the frame 510 between the first and intermediate support walls 506, 508 of the frame 510. As shown, each of the support walls 506, 507, 508 extend inwardly towards the solar module 500a-i from the sidewall 505 and the bifacial solar module 500a-I is stored between at least two of the support walls 506, 507, 508. Each of the support walls 506, 507, 508 being generally parallel to each other and generally perpendicular to the side wall 505.

In some embodiments, as shown in FIGS. 5A-5C, the strips of the HRF or HRC 570 are positioned on at least one of the outside surfaces 521, 561 of the framed bifacial solar module 500a-c, and particularly the outside of the first or second transparent support layers 520, 560. In such embodiments, the strips of HRF or HRC 570 may include an adhesive (not shown) to secure each strip 570 to the outer surface 521, 561. When positioned on an outer surface, each strip may be added or applied separately to the transparent support layers before formation of the solar module, after the formation of the solar module, before the framing of the solar module, and/or after the framing the solar module.

In some embodiments, as shown in FIGS. 5D-5G, the strips of the HRF or HRC 570 are positioned on at least one inside surface of the framed bifacial solar module 500d-g. For example, in some embodiments, the strips of the HRF or HRC 570 may be positioned between the first transparent support layer 520 and the first encapsulation layer 530, the second transparent support layer 560 and the second encapsulation layer 550, or both (see, e.g., FIGS. 5D-5F).

As shown in FIG. 5G, in some embodiments, the strips of HRF or HRC 570 are encapsulated within the center of the solar module 500g between the first and second encapsulant layers 530, 550 and positioned within the gaps 545 between the solar cells 540. In such embodiments, each of the strips 570 fill the gap 545 in the same plane as the solar cells 540.

In some embodiments, the plurality of strips of HRF or HRC may be positioned all within the same layer of the framed bifacial solar module (see, e.g., FIGS. 5A, 5B, 5D, 5E, 5G). In some embodiments, the plurality of strips of HRF or HRC may be positioned in two or more different layers of the framed bifacial solar module (see, e.g., FIGS. 5C and 5F). In some embodiments, the plurality of strips of HRF or HRC may be positioned only on an inside surface of the framed bifacial solar module. (see, e.g., FIGS. 5D-5G). In some embodiments, the plurality of strips of HRF or HRC may be encapsulated within the center of the framed bifacial solar module (see, e.g., FIG. 5G).

In FIGS. 5H-5I, further aspects of the framed bifacial solar modules 500h-i are depicted wherein the HRF or HRC 570 is applied not just to and within the solar module, but also to portions of the frame 510. In some embodiments, the strips of HRF or HRC 570 are positioned on or extend from at least one of the sidewall 505, the second support wall 507, or both. In particular embodiments, the HRF or HRC 570 can be positioned between the second support wall 507 and the intermediate support wall 508 and at an angle relative to the sidewall 505. These sections of HRF or HRC 570 on the frame 510 are also used to redirect light back onto the solar cells 540 and generate electrical energy.

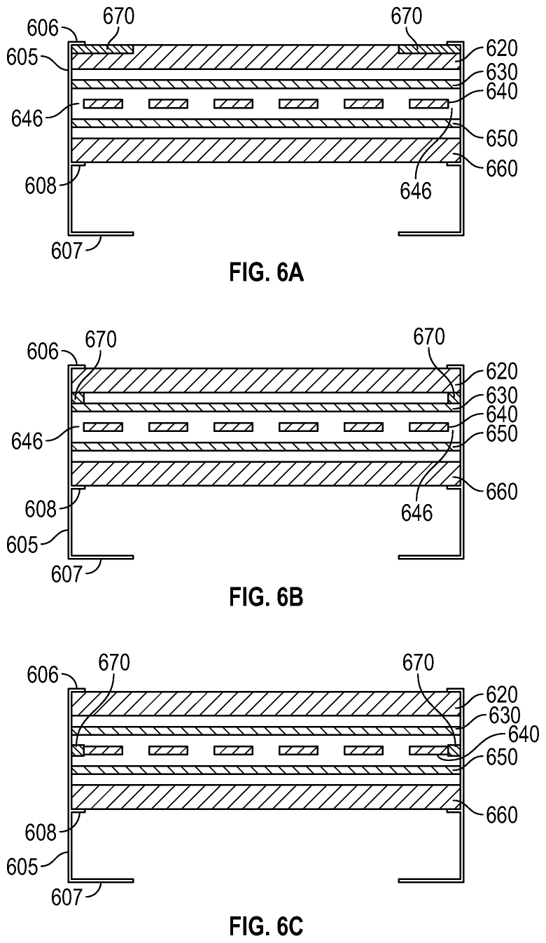

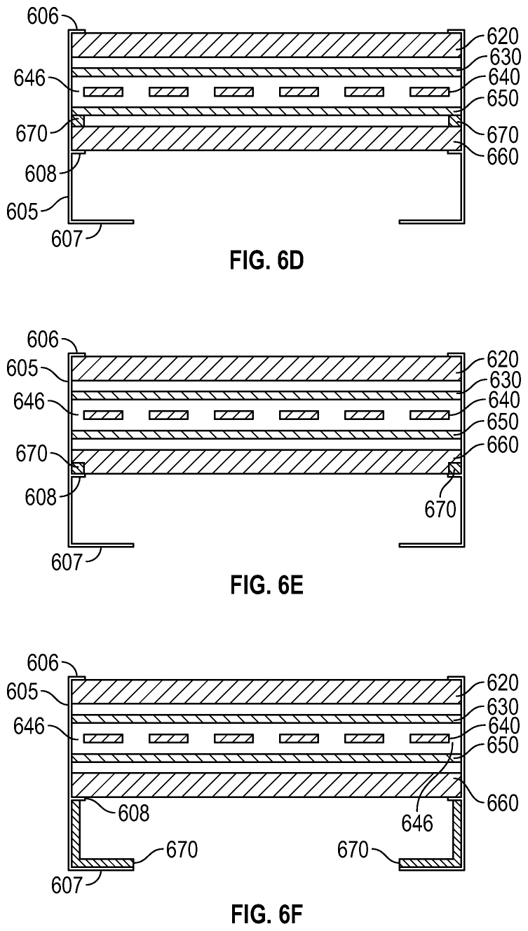

In FIGS. 6A-6F, further aspects of the framed bifacial solar modules 600a-f are depicted wherein the HRF or HRC 670 is further positioned along the outer edges of the solar module 600a-f to also redirect sunlight back onto the solar cells 640 and generate electrical energy. In FIGS. 6A and 6E, the HRF or HRC 670 is shown positioned on the outside of the solar module 600a, 600e similar to the HRF or HRC 570 shown in FIGS. 5A-5B, however the HRF or HRC 670 is also connected to a portion of the frame 610 and vertically aligned with the edge gap 646 to help reduce or prevent shading along the frame or outer edge of the solar module 600a, 600e. In some embodiments, the HRF or HRC 670 is connected to both an outside surface of the solar module 600a and the first support wall 606. In some embodiments, the HRF or HRC 670 is connected to both an outside surface of the solar module 600e and the intermediate support wall 608.

In FIGS. 6B-6D, the HRF or HRC 670 is shown positioned on the inside of the solar module 600b-d similar to the HRF or HRC 570 shown in FIGS. 5D-5F, however the HRF or HRC 670 is vertically aligned with the edge gap 646 to help reduce or prevent shading along the frame or outer edge of the solar module from inside the solar module 600b-d. In FIG. 6F the HRF or HRC 670 is shown positioned on a portion of the frame 610 beneath the solar module 600f, and specifically on both a portion of the sidewall 605 and a portion of the second support wall 607.

In addition to the several different embodiments individually depicted in the present Figures, it is further envisioned that in some embodiments, the solar modules described herein may position the HRF or HRC in various combinations of the Figures. For example, in some embodiments, the solar modules described herein may include HRF or HRC which is vertically aligned with the gap between the cells (see, e.g., FIGS. 4A-5E) and the edge gap between the outermost solar cell and the outermost edge of the solar module or frame (see, e.g., FIGS. 6A-6E). In such embodiments, the HRF or HRC may be positioned on or within the same or different layers of the solar module and/or may be positioned on the same or different portions of the frame.

Although embodiments have been described in detail with reference to the accompanying drawings for illustration and description, it is to be understood that the inventive processes and apparatus are not to be construed as limited thereby. It will be apparent to those of ordinary skill in the art that various modifications to the foregoing embodiments may be made without departing from the scope of the disclosure.

What is claimed is:

1. A bifacial solar module with enhanced power output comprising:
a first transparent support layer;
a first encapsulating layer;
a plurality of electrically interconnected bifacial solar cells with gaps between the interconnected bifacial solar cells;
a second encapsulating layer, a second transparent support layer; and
one or more highly reflective films or coatings attached to the solar module at the gaps between the bifacial solar cells or an edge gap at a peripheral edge of the solar module beyond the bifacial solar cells, wherein the films or coatings redirect light impacting them such that the light is directed towards at least one of the bifacial solar cells.

2. The bifacial solar module of claim 1, wherein the first encapsulating layer and the second encapsulating layer are arranged between the first and second transparent support layers.

3. The bifacial solar module of claim 2, wherein the plurality of electrically interconnected bifacial solar cells are arranged between the first and second encapsulating layers.

4. The bifacial solar module of claim 1, wherein the one or more highly reflective films or coatings are positioned on an outer surface of at least one of the first or second transparent support layers.

5. The bifacial solar module of claim 1, wherein the one or more highly reflective films or coatings are positioned between the first transparent support layer and the first encapsulating layer, the second transparent support layer and the second encapsulating layer, or both.

6. The bifacial solar module of claim 1, wherein the one or more highly reflective films or coatings are encapsulated within the same layer of the solar cells and positioned within the gaps.

7. The bifacial solar module of claim 1, wherein the one or more highly reflective films or coatings are vertically aligned with at least one of the gaps or edge gaps of the solar module.

8. A framed bifacial solar module with enhanced power output comprising:
a frame configured to receive and secure a bifacial solar module, the bifacial module including:
a first and second transparent support layer;
a first and second encapsulating layer arranged between the first and second transparent support layers;
a plurality of electrically interconnected bifacial solar cells with gaps between the interconnected bifacial solar cells and arranged between the first and second encapsulating layers; and
one or more highly reflective films or coatings attached to the solar module at the gaps between the bifacial solar cells or an edge gap at a peripheral edge of the solar module beyond the bifacial solar cells, wherein the films or coatings redirect light impacting them such that the light is directed towards at least one of the bifacial solar cells.

9. The bifacial solar module of claim 8, wherein the first encapsulating layer and the second encapsulating layer are arranged between the first and second transparent support layers.

10. The bifacial solar module of claim 9, wherein the plurality of electrically interconnected bifacial solar cells are arranged between the first and second encapsulating layers.

11. The bifacial solar module of claim 8, wherein the one or more highly reflective films or coatings are positioned on an outer surface of at least one of the first or second transparent support layers.

12. The bifacial solar module of claim 8, wherein the one or more highly reflective films or coatings are positioned between the first transparent support layer and the first encapsulating layer, the second transparent support layer and the second encapsulating layer, or both.

13. The bifacial solar module of claim 8, wherein the one or more highly reflective films or coatings are encapsulated within the same layer of the solar cells and positioned within the gaps.

14. The bifacial solar module of claim 8, wherein the one or more highly reflective films or coatings are vertically aligned with at least one of the gaps or edge gaps of the framed solar module.

15. The bifacial solar module of claim 8, wherein a cross-section of the frame includes a side wall having a length defined between a first and second end thereof, the first end having a top support wall extending therefrom, the second end having a bottom support wall extending therefrom, and a portion along the length of the frame between the first and second ends including an intermediate support wall extending therefrom, wherein the bifacial solar module is received and secured within the frame between the top and intermediate support walls of the frame.

16. The bifacial solar module of claim 15, wherein the one or more highly reflective films or coatings are positioned on a surface of the second bottom support wall facing the solar module.

17. The bifacial solar module of claim 16, wherein the one or more highly reflective films or coatings are further positioned on an inner surface of the sidewall between the second bottom support wall and the intermediate support wall.

18. The bifacial solar module of claim 15, wherein the one or more highly reflective films or coatings are positioned at an angle relative to the solar module and extending from the sidewall near the intermediate support wall towards a free end of the second bottom support wall.

19. A solar power kit comprising:
a frame configured to receive and secure a bifacial solar module, and
a bifacial solar module including a first and second transparent support layer;
a first and second encapsulating layer arranged between the first and second transparent support layers;
a plurality of electrically interconnected bifacial solar cells with gaps between the interconnected bifacial solar cells and arranged between the first and second encapsulating layers; and
one or more highly reflective films or coatings attached to the solar module at the gaps between the bifacial solar cells or a peripheral edge of the solar module beyond the bifacial solar cells, wherein the films or coatings redirect light impacting them such that the light is directed towards at least one of the bifacial solar cells.
